(19) United States
(12) Patent Application Publication
(10) Pub. No.: US 2003/0086368 A1
(43) Pub. Date: May 8, 2003

(54) Fault-tolerant mesh network comprising interlocking ring networks

(76) Inventors: Pradeep Shrikrishna Limaye, Westfield, NJ (US); Sasisekharan Raguram, Hillsborough, NJ (US)

Correspondence Address: DEMONT & BREYER, LLC, PO BOX 7490, SHREWSBURY, NJ, 07702, US

(21) Appl. No.: 09/969,703

(22) Filed: Oct. 3, 2001

Related U.S. Application Data
(63) Continuation-in-part of application No. 09/909,550, filed on Jul. 20, 2001.

(51) Int. Cl. G01R 31/08

(52) U.S. Cl. 370/216; 370/406; 714/1

(57) ABSTRACT

A SONET/SDH mesh network architecture is disclosed that restores quickly after the failure of a network element and can be administered and maintained, for most purposes, as a collection of distinct ring networks. The SONET/SDH mesh network is fabricated from a plurality of “interlocking” ring networks. By fabricating a mesh network as a plurality of interlocking ring networks, a protected service can be restored in the event of a failure in a distributed, timely, and efficient manner. The illustrative embodiment comprises: a first SONET/SDH ring; a second SONET/SDH ring; and a node that monitors the status of an automatic protection switching channel in the first SONET/SDH ring and that affects the routing of traffic in the second SONET/SDH ring based on the status of an automatic protection switching channel in the first SONET/SDH ring.

### CROSS-REFERENCE TO RELATED APPLICATIONS

This application is a continuation-in-part of U.S. patent application Ser. No. 09/909,550, filed Jul. 20, 2001, and entitled “Interlocking SONET/SDH Network Architecture.”

### FIELD OF THE INVENTION

The present invention relates to telecommunications in general, and, more particularly, to fault-tolerant mesh networks, which are commonly used in high-speed backbone networks (e.g., SONET/SDH networks, etc.).

### BACKGROUND OF THE INVENTION

The first generation of optical fiber systems in the public telephone network used proprietary architectures, equipment line codes, multiplexing formats, and maintenance procedures. This diversity complicated the task of the Regional Bell Operating Companies and the interexchange carriers who needed to interface their equipment with these diverse systems.

To ease this task, Bellcore initiated an effort to establish a standard for connecting one optical fiber system to another. That standard is officially named the Synchronous Optical Network, but it is more commonly called “SONET.” The international version of the standard is officially named the Synchronous Digital Hierarchy, but it is more commonly called “SDH.”

Although differences exist between SONET and SDH, those differences are mostly in terminology. In virtually all practical aspects, the two standards are operationally compatible, and, therefore, virtually all of the equipment that complies with either the SONET standard or the SDH standard also complies with the other. For the purposes of this specification, the combined acronym/initialism “SONET/SDH” is defined as the Synchronous Optical Network or the Synchronous Digital Hierarchy or both the Synchronous Optical Network and the Synchronous Digital Hierarchy.

SONET/SDH networks have traditionally been deployed in a ring topology. A ring is advantageous because it restores quickly in the event of a disruption and because it is simple to administer. A ring is, however, disadvantageous because of its topological inflexibility.

Because of their topological flexibility, a great deal of interest has arisen in deploying SONET/SDH mesh networks. A SONET/SDH mesh network is disadvantageous in comparison to a ring, however, because a mesh network typically restores more slowly in the event of the failure of a network element and because a mesh is more complex to administer than a ring.

Therefore, the need exists for a new and improved SONET/SDH network architecture that avoids some of the costs and disadvantages associated with SONET/SDH network architectures in the prior art.

### SUMMARY OF THE INVENTION

The present invention provides a mesh network architecture that avoids some of the costs and disadvantages associated with mesh network architectures in the prior art.

For example, the illustrative embodiment is a mesh network whose protected services can be restored quickly after the failure of a network element (i.e., a network node, a network transmission facility). Furthermore, the protected services can be restored after all single and most multiple network-element failures as quickly as a ring network can recover from a single network-element failure. And still furthermore, the illustrative embodiment is also advantageous in that it can be administered and maintained, for most purposes, as a collection of distinct ring networks. This is beneficial because ring networks are easy to administer and maintain and also because most network service providers are already familiar with administering and maintaining ring networks.

In accordance with the illustrative embodiment, a mesh network is fabricated from a plurality of “interlocking” ring networks. Each of the ring networks that compose the mesh network can be, but is not necessarily, interlocked with each other, although each of the ring networks must be interlocked with at least one of the other ring networks.

Two ring networks are considered to be interlocking when the failure of a network element in one ring network can, but does not necessarily, alter some aspect of the operation of the second ring network. This is in contrast with dual-ring interworking (“DRI”) in which the failure of a network element in one ring network does not affect the operation of a second ring network.

Two or more interlocking ring networks are conjoined at one or more “ring interworking nodes.” A ring interworking node is a node in two or more interlocking ring networks that:

i. can transfer traffic (e.g., one or more STS-1's, etc.) between one ring and another ring during nominal operation, and

ii. can monitor, originate, access, modify or terminate transport overhead (e.g., payload pointer bytes, automatic protection switching bytes, error monitoring bytes, etc.) in a SONET/SDH frame, and

iii. can initiate or terminate the transfer of traffic between one ring and a second ring based on the failure of a network element in either ring, and

iv. can alter the operation (e.g., the routing of traffic, etc.) of one ring based on the failure of a network element in a second (or third) ring.

When a protected service is provisioned through the illustrative embodiment, the service and its protection bandwidth are provisioned either through one ring network or through a series of two or more interlocking ring networks. When a protected service is provisioned through only one ring network, both the service bandwidth and the protection bandwidth are provisioned in the ring in well-known fashion. In this case, the failure of one or more network elements supporting the service is detected and promulgated (e.g., through the automatic protection switching channel, etc.) and handled in the same manner as a failure in a ring in the prior art.

In contrast, when a protected service is provisioned through two or more interlocking ring networks, both service bandwidth and protection bandwidth are provisioned in each ring and in the conduits between the applicable rings. Whenever the service bandwidth passes between two rings, it passes at a ring interworking node called a “primary transfer node.” Whenever the protection bandwidth passes between two rings, it passes at a ring interworking node called a “secondary transfer node.” A primary transfer node and a secondary transfer node are relative designations that are given on a service by service basis, and, therefore, one node can be both a primary transfer node and a secondary transfer node for different services.

When a protected service is provisioned through a primary transfer node, the failure of any network element other than the primary transfer node is detected and promulgated (e.g., through the automatic protection switching channel, etc.) and handled in the same manner as a failure in a ring in the prior art. In other words, the fabrication of the mesh network out of interlocked ring networks enables service failures not involving a primary transfer node to be restored in the same manner as with a ring network in the prior art.

In contrast, when a primary transfer node fails, the failure is detected and promulgated (e.g., through the automatic protection switching channel, etc.) in the same manner as a failure in a ring in the prior art. Furthermore, all of the nodes in the ring, except the secondary transfer node, handle the restoration in the same manner as with a ring network in the prior art. The secondary transfer node, however, handles the restoration by re-routing the service between the two rings and around the failed primary transfer node. Again, this restoration is handled on a service by service basis.

By fabricating a mesh network as a plurality of interlocking ring networks, a protected service can be restored in the event of a failure in a distributed, timely, and efficient manner.

The illustrative embodiment comprises: a first SONET/SDH ring; a second SONET/SDH ring; and a node that monitors the status of an automatic protection switching channel in the first SONET/SDH ring and that affects the routing of traffic in the second SONET/SDH ring based on the status of an automatic protection switching channel in the first SONET/SDH ring.

### BRIEF DESCRIPTION OF THE DRAWINGS

FIG. 1 depicts a schematic diagram of a mesh network in accordance with the illustrative embodiment of the present invention.

FIG. 2 depicts a schematic diagram of the mesh network of FIG. 1 and how it was resolved into three constituent ring networks.

FIG. 3 depicts a schematic diagram of the mesh network of FIG. 1 and the logical nodes and their interrelationship within the physical nodes.

FIG. 4 depicts a block diagram of the salient components of a node in accordance with the illustrative embodiment.

### DETAILED DESCRIPTION

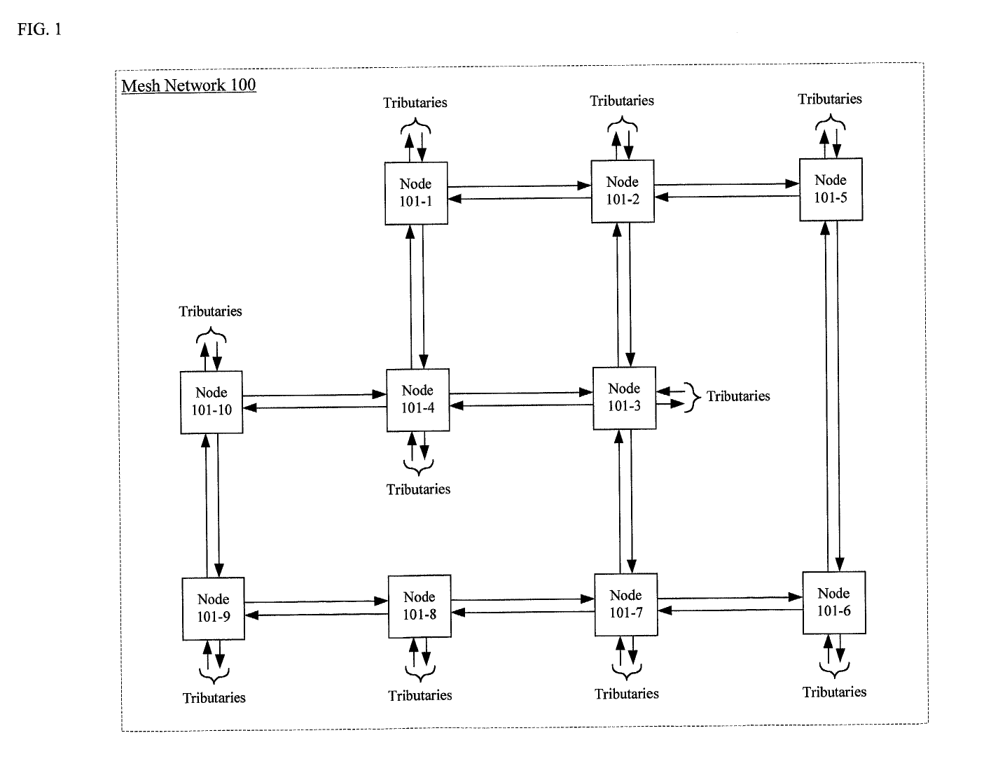

FIG. 1 depicts a schematic diagram of a mesh network in accordance with the illustrative embodiment of the present invention. For the purposes of this specification, a “mesh network” is defined as an arrangement of interconnected nodes in which:

1. each node is directly connected by a logical communications link with at least two other nodes, and

2. at least one node is directly connected by a logical communications link with at least three other nodes, and

3. there exists a logical path through the mesh network between each pair of nodes (i.e., each pair of nodes are directly or indirectly connected by one or more logical communications links).

For the purposes of this specification, a “node” is defined as:

i. a switch, or

ii. a time-slot interchanger, or

iii. a multiplexor, or

iv. a demultiplexor, or

v. any combination of i, ii, iii, and iv.

Mesh network 100 comprises ten nodes, nodes 101-1 through 101-10, which are interconnected by logical communications links in the depicted topology. Although the illustrative embodiment is depicted as comprising ten nodes, it will be clear to those skilled in the art how to make and use embodiments of the present invention that comprise four or more nodes. Furthermore, although mesh network 100 has one particular mesh topology, it will be clear to those skilled in the art how to make and use embodiments of the present invention that have any mesh topology.

In accordance with the illustrative embodiment, a mesh network defines an address space such that each node in the mesh network has a unique address in that address space. The address of a node in the address space of mesh network 100 is used, by various entities and for various purposes, to distinguish between the nodes in mesh network 100. It will be clear to those skilled in the art how to use the address of a node in the address space of mesh network 100.

Table 1 depicts the address of each of nodes 101-1 through 101-10 in the address space of mesh network 100.

TABLE 1
Node Addresses in Address Space of Mesh network 100

| | Node's Address in Address Space |
|---|---|
| Node | of Mesh network 100 |
| 101-1 | 0 |
| 101-2 | 1 |
| 101-3 | 2 |
| 101-4 | 3 |
| 101-5 | 4 |
| 101-6 | 5 |
| 101-7 | 6 |
| 101-8 | 7 |
| 101-9 | 8 |
| 101-10 | 9 |

It will be clear to those skilled in the art how to assign and use addresses for each node in alternative embodiments of the present invention.

As shown in FIG. 1, each of nodes 101-1 through 101-10 is capable of receiving and spawning tributaries, which tributaries provide access to and from mesh network 100. It will be clear to those skilled in the art how to make and use embodiments of the present invention in which some or all of the nodes are capable of:

i. receiving one or more tributaries, or

ii. spawning one or more tributaries, or

iii. both i and ii.

Furthermore, in accordance with the illustrative embodiment, some of the tributaries have different data rates (e.g., STS-768 vs. STS-192, etc.) than some other tributaries and some of the tributaries operate in accordance with a different protocol (e.g., Fibre Channel vs. SONET/SDH, Gigabit Ethernet vs. TCP/IP, etc.) than some of the other tributaries. The functionality provided by each of nodes 101-1 through 101-10 is described in detail below and in the accompanying figures.

Some pairs of nodes in mesh network 100 are connected with a logical communications link. In accordance with the illustrative embodiment, each logical communications link is carried by a pair of optical fibers that carry OC-N signals in opposite directions. In some alternative embodiments of the present invention, some or all of the logical communications links are carried by a different kind of transmission facility (e.g., metallic wireline, wireless, etc.).

In accordance with the illustrative embodiment, each node in mesh network 100 originates and terminates SONET/SDH lines. As is well known to those skilled in the art, a node can therefore originate, access, modify or terminate line overhead (e.g., payload pointer bytes, automatic protection switching bytes, error monitoring, etc.) in a SONET/SDH frame. For this reason, the illustrative embodiment can be considered a SONET/SDH mesh network.

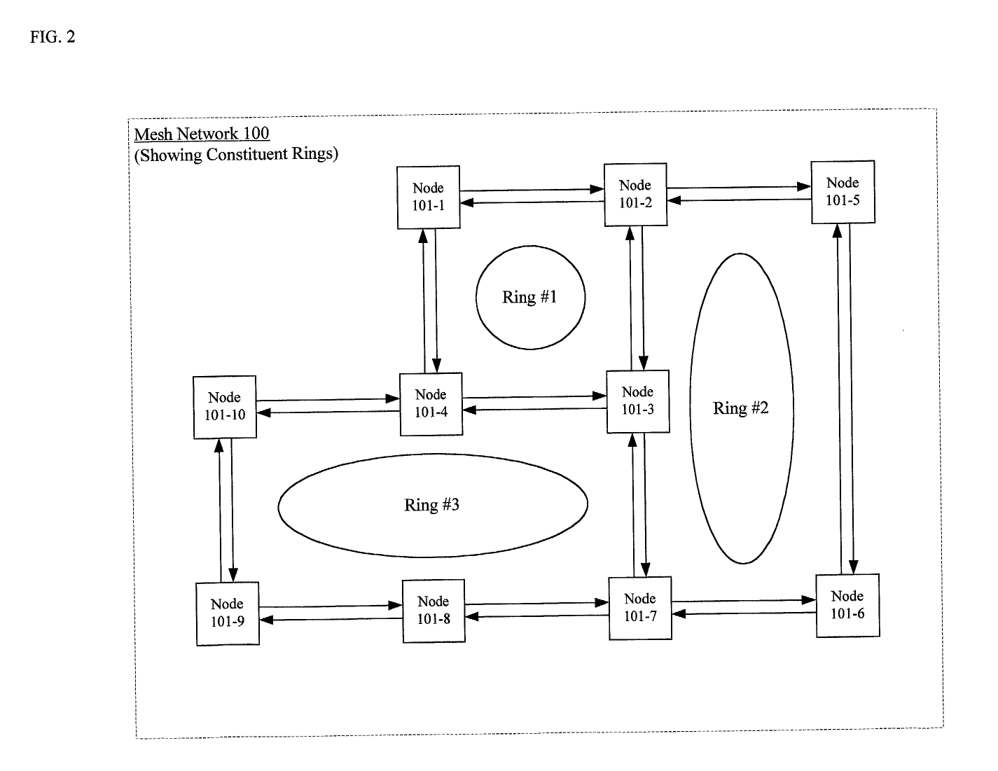

In accordance with the illustrative embodiment, mesh network 100 is fabricated from a plurality of interlocking ring networks. FIG. 2 depicts a schematic diagram of mesh network 100 and the three constituent ring networks from which it is fabricated. In accordance with the illustrative embodiment, mesh network 100 is fabricated from a plurality of constituent ring networks such that each node in mesh network 100 is also in at least one of the constituent ring networks. For the purposes of this specification, a “ring network” is defined as two or more nodes and logical communications links that form a closed loop. For the purposes of this specification, a “ring” is defined as a ring network.

As depicted in FIG. 2, mesh network 100 comprises three constituent ring networks: ring #1, ring, #2, and ring #3. Ring network #1 comprises: nodes 101-1, 101-2, 101-3, and 101-4. Ring network #2 comprises: nodes 101-2, 101-3, 101-5, 101-6, and 101-7, and ring network #3 comprises nodes 101-3, 101-4, 101-7, 101-8, 101-9, and 101-10.

It will be clear to those skilled in the art how, using well-known graph theory techniques, to determine which combinations of constituent ring networks exist such that each node in a mesh network is also in at least one of the constituent ring networks. For example, mesh network 100 could be fabricated from many combinations of seven constituent rings. Table 2 depicts, in tabular form, the ten nodes in mesh network 100 and their membership in each of the seven constituent rings.

TABLE 2
Membership of Nodes in Constituent Rings

| | Ring | | | | | | |
|---|---|---|---|---|---|---|---|
| Node | #1 | Ring #2 | Ring #3 | Ring #4 | Ring #5 | Ring #6 | Ring #7 |
| 101-1 | x | | | x | x | | x |
| 101-2 | x | x | | x | x | x | x |
| 101-3 | x | x | x | x | x | x | |
| 101-4 | x | | x | x | x | x | x |
| 101-5 | | x | | x | | x | x |
| 101-6 | | x | | x | | x | x |
| 101-7 | | x | x | x | x | x | x |
| 101-8 | | | x | | x | x | x |
| 101-9 | | | x | | x | x | x |
| 101-10 | | | x | | x | x | x |

Advantageously, a mesh network comprises the smallest number of constituent ring networks that satisfy the condition that each node in the mesh network is also in at least one of the constituent ring networks. Although the illustrative embodiment comprises three constituent rings (for pedagogical reasons), it will be clear to those skilled in the art that mesh network 100 could alternatively be fabricated from two rings. For example,

ring #1 and ring #6,

ring #1 and ring #7,

ring #4 and ring #5,

ring #4 and ring #6,

ring #4 and ring #7,

ring #5 and ring #6,

ring #5 and ring #7,

all satisfy the condition that each node in mesh network 100 is also in at least one of the constituent ring networks.

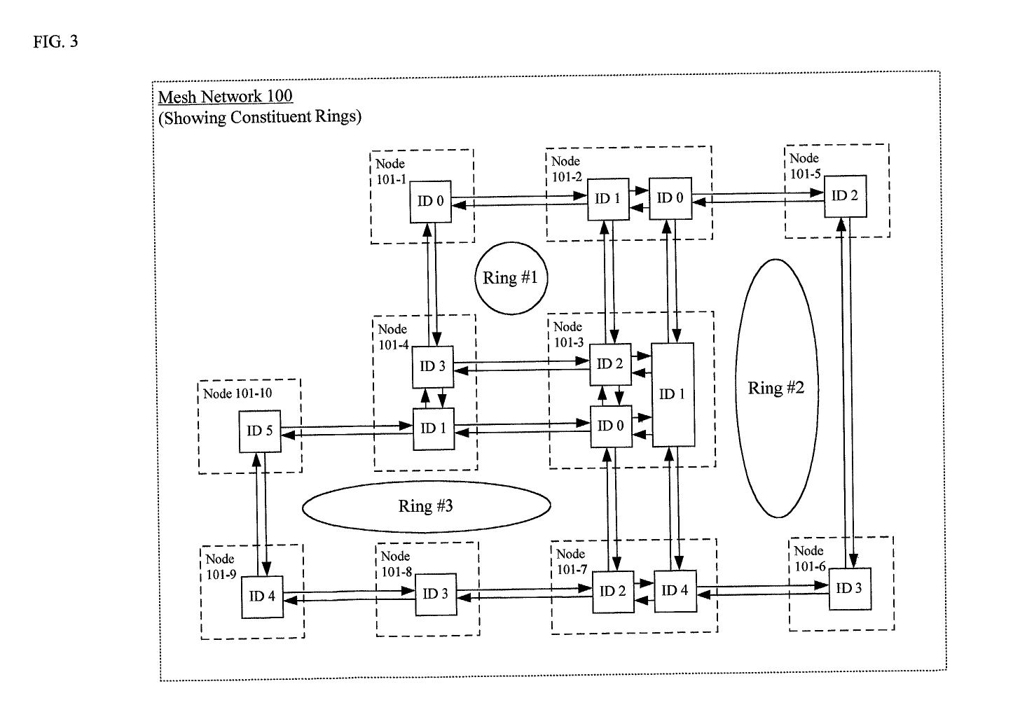

FIG. 3 depicts a block diagram of how the three ring networks logically relate to mesh 20 network 100. As can be seen in FIG. 3, some nodes in mesh network 100 only comprise one node in one of the three ring networks. Nodes 101-1, 101-5, 101-6, 101-8, 101-9, and 101-10 are like this. In contrast, some of the nodes in mesh network 100 comprise a node in two or more of the three ring networks. Nodes 101-2, 101-3, 101-4, and 101-7 are like this.

In accordance with the illustrative embodiment, each ring network defines a distinct address space and each node in each ring is identified by a unique address (or “ID”) in the address space of that ring. Therefore, a node in accordance with the illustrative embodiment has a unique address in the address space of mesh network 100 and a unique address in the address space of each ring of which it is a member.

In accordance with the illustrative embodiment, nodes 101-1, 101-2, 101-3, and 101-4 are assigned the following addresses in the address space of Ring #1:

TABLE 3
Node Addresses for Ring #1

| Node | Ring #1 Node ID |
|---|---|
| node 101-1 | 0 |
| node 101-2 | 1 |
| node 101-3 | 2 |
| node 101-4 | 3 |

In accordance with the illustrative embodiment, nodes 101-2, 101-3, 101-5, 101-6, and 101-7 are assigned the following addresses in the address space of Ring #2:

TABLE 4
Node Addresses for Ring #2

| Node | Ring #2 Node ID |
|---|---|
| node 101-2 | 0 |
| node 101-3 | 1 |
| node 101-5 | 2 |
| node 101-6 | 3 |
| node 101-7 | 4 |

In accordance with the illustrative embodiment, nodes 101-3, 101-4, 101-7, 101-8, 101-9, and 101-10 are assigned the following addresses in the address space of Ring #3:

TABLE 5
Node Addresses for Ring #3

| Node | Ring #3 Node ID |
|---|---|
| node 101-3 | 0 |
| node 101-4 | 1 |
| node 101-7 | 2 |
| node 101-8 | 3 |
| node 101-9 | 4 |
| node 101-10 | 5 |

It will be clear to those skilled in the art how to similarly assign addresses for each node in the address space of each of the constituent rings.

Table 6 consolidates the information in Tables 1, 3, 4, and 5.

TABLE 6
Addresses for Each Node in Mesh network 100 and Rings #1, #2, and #3

| | Mesh network 100 | Ring #1 | Ring #2 | Ring #3 |
|---|---|---|---|---|
| Node | Address | Node ID | Node ID | Node ID |
| node 101-1 | 0 | 0 | — | — |
| node 101-2 | 1 | 1 | 0 | — |
| node 101-3 | 2 | 2 | 1 | 0 |
| node 101-4 | 3 | 3 | — | 1 |
| node 101-5 | 4 | — | 2 | — |
| node 101-6 | 5 | — | 3 | — |
| node 101-7 | 6 | — | 4 | 2 |
| node 101-8 | 7 | — | — | 3 |
| node 101-9 | 8 | — | — | 4 |
| node 101-10 | 9 | — | — | 5 |

Each of rings #1, #2, and #3 have an automatic protection switching channel for the service protection for that ring. In other words, mesh network 100 comprises three automatic protection switching channels, each of which is responsible for guarding a portion of mesh network 100.

The current SONET/SDH standard specifies that it is an address in the address space of a ring that is carried in the K₁ and K₂ bytes of the automatic protection switching channel of an STS-N frame. In accordance with the current SONET/SDH standard, the address space of a single ring is limited to 16 nodes.

In some alternative embodiments of the present invention, the address space of a single ring is greater than 16 nodes. For example, one or more address extension bytes can be specified and carried in an undefined portion of the STS-N frame transport overhead and used to augment the K₁ and K₂ bytes. Furthermore, it will be clear to those skilled in the art that embodiments of the present invention are useable whether the extension of the address space is made in accordance with a change to the SONET/SDH standard or in accordance with an independent or proprietary modification to the SONET/SDH standard.

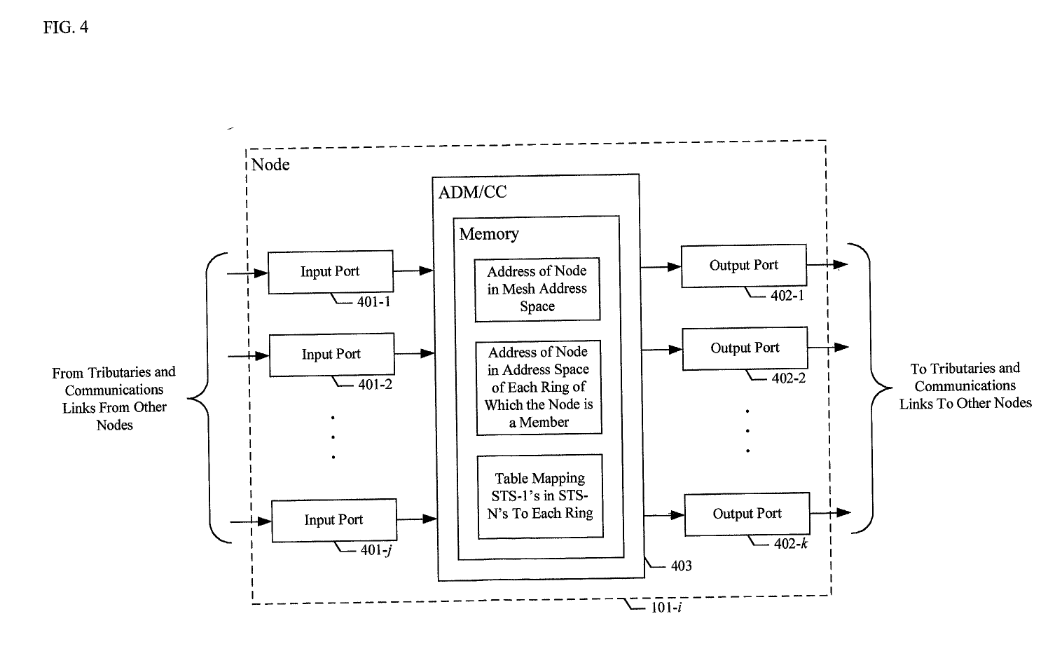

A mesh network node that comprises a node in two or more of the three ring networks can be, but is not advantageously, a mere amalgam of two SONET/SDH nodes as logically depicted in FIG. 3. On the contrary, a node in two or more of the three ring networks is advantageously a unified structure as depicted in FIG. 4.

Furthermore, although two logical communications links are shown between some pairs of mesh network nodes, in the first variation of the illustrative embodiment, each pair of communications links is carried by a distinct transmission facility. In the second variation of the illustrative embodiment, some or all of the pairs of communications links are carried by a shared transmission facility. For example, the two communications links from node 101-4 to node 101-3 could be wavelength division multiplexed onto a single optical fiber. Or alternatively, the two communications links could be STS-division multiplexed into a single SONET/SDH frame as taught by U.S. patent application Ser. No. 09/909,550, filed Jul. 20, 2001, and entitled “Interlocking SONET/SDH Network Architecture, which is incorporated by reference.

FIG. 4 depicts a block diagram of the salient components of node 101-i, wherein i=1 to 10. Node 101-i comprises add/drop multiplexor-cross-connect (“ADM/CC”) 403, input ports 401-1 through 401-j, wherein j is a positive integer greater than one, and output ports 402-1 through 402-k, wherein k is a positive integer greater than one and wherein j plus k are greater than 2.

Each of input ports 401-1 through 401-j receives a signal (e.g., a low-rate tributary, a STS-N, etc.) from an optical fiber or other transmission facility (e.g., metallic wireline, microwave channel, etc.) and passes the signal to ADM/CC 403, in well-known fashion.

For the purposes of this specification, a “STS-N” is defined to comprise N STS-1's. For example, an STS-768 comprises 768 STS-1's plus the overhead of the STS-768. Furthermore, for the purposes of this specification, a “STS-N frame” is defined to comprise N STS-1 frames. For example, an STS-768 frame comprises 768 STS-1 frames.

Each of output ports 402-1 through 402-k receives a signal from ADM/CC 403 and transmits the signal via an optical fiber or other transmission facility, in well-known fashion.

When node 101-i receives a signal from one or more tributaries, ADM”ICC 403 enables node 101-i to add the tributaries into one or more STS-N's. When node 101-i transmits a signal via one or more tributaries, ADM/CC 403 enables node 101-i to drop the tributaries from one or more STS-N's. When node 101-i has an address in the address space of two or more rings, ADM/CC 403 enables node 101-i to switch all or a portion of an STS-N from one ring to an STS-N on another ring. When node 101-i receives an STS-N that comprises STS-1's associated with different rings, ADM/CC 403 enables node 101-i to demultiplex the STS-1's, associate each with its respective ring, and transmit each STS-1 onto an optical fiber for the ring associated with the STS-1. And when node 101-i receives two or more STS-N's that are each associated with different rings, ADM/CC 403 enables node 101-i to multiplex the STS-1's and transmit them via a single optical fiber while maintaining their association with their respective rings.

When node 101-i receives or transmits an STS-N that comprises two or more STS-1's that are associated with different rings, node 101-i is informed during provisioning which STS-1's are to be associated with which ring. This information is stored by ADM/CC 403 in a table that maps each STS-1 in each STS-N to a ring. Table 7 depicts a portion of such a table.

For example, node 101-3 is capable of receiving an STS-48 from node 101-4 that comprises 6 traffic and 6 protection STS-1's associated with Ring #1 and also 6 traffic and 6 protection STS-1's associated with Ring #3. (The other 24 STS-1's are either empty, or are carrying point-to-point traffic on a path from node 101-3 to 101-4, or are carrying unprotected traffic.) Therefore, during provisioning, a table in node 101-3 is populated to indicate which ring node 101-3 is to be associated with each STS-1 in the STS-48.

TABLE 7
Mapping of STS-1's To Rings In Node 101-3 For STS-48 Arriving
From Node 101-4.

| STS-1 | Associated Ring |
|---|---|
| 1 | Ring 101 (traffic) |
| . . . | . . . |
| 6 | Ring 101 (traffic) |
| 7 | Ring 101 (protection) |
| . . . | . . . |
| 12 | Ring 101 (protection) |
| 13 | Ring 103 (traffic) |
| . . . | . . . |
| 18 | Ring 103 (traffic) |
| 19 | Ring 103 (protection) |
| . . . | . . . |
| 24 | Ring 103 (protection) |
| 25 | empty or carrying other traffic |
| . . . | . . . |
| 48 | empty or carrying other traffic |

When node 101-i receives or transmits an STS-N that comprises two or more STS-1's that are associated with different rings, the STS-N comprises an automatic protection switching channel for each of the different rings.

In other words, when an STS-48 carries 12 STS-1's from a first ring and 12 STS-1's from a second ring, the STS-48 carries:

1. the automatic protection switching channel for the 12 STS-1's from the first ring (with addresses specified in the address space of the first ring); and

2. the automatic protection switching channel for the 12 STS-1's from the second ring (with addresses specified in the address space of the second ring).

Furthermore, node 101-i:

1. associates and applies the automatic protection switching channel for the 12 STS-1's from the first ring only to the 12 STS-1's from the first ring, and

2. associates and applies the automatic protection switching channel for the 12 STS-1's from the second ring only to the 12 STS-1's from the second ring.

The current SONET/SDH standard specifies how each STS-N is to carry and use its automatic protection switching channel. First, the current SONET/SDH standard specifies that each STS-N carries only one automatic protection switching channel. Second, the current SONET/SDH standard specifies that the automatic protection switching channel is to be carried in the K₁ and K₂ line overhead bytes of the overhead of the first STS-1 of the STS-N. Third, the current SONET/SDH standard specifies that the automatic protection switching channel is to be associated with and applied to all of the STS-1's in the STS-N. And fourth, the current SONET/SDH standard specifies that the bytes in row 5, columns 2 and 3 of the second through Nth STS-1's of the STS-N are undefined.

In contrast, and in accordance with the illustrative embodiment of the present invention, each STS-N carries one automatic protection switching channel for each ring represented in the STS-N. Second, the mth automatic protection switching channel is carried in the bytes in row 5, columns 2 and 3 of the mth STS-1. Third, the mth automatic protection switching channel is to be associated with and applied only to the STS-1's associated with the ring associated with the mth automatic protection switching channel. Towards this end, node 101-i comprises the data, such as that depicted in Tables 8 and9, that enables node 101-i to know the location of the automatic protection switching channels in an STS-N and to know which STS-1's in the STS-N are to be associated with which automatic protection switching channels.

Continuing with the example depicted in Table 7, Table 8 indicates how node 101-i knows the location of the automatic protection switching channels in the STS-N (for N=48). In some alternative embodiments of the present invention, the automatic protection switching channels are placed elsewhere in the STS-N.

TABLE 8
Location of Automatic Protection Switching Channels in STS-48 for
1 ≦ m ≦ 2.

| m | Location of mth automatic protection switching channel in STS-48 |
|---|---|
| 1 | the bytes in row 5, columns 2 and 3 of the 1st STS-1 of the STS-48 |
| 2 | the bytes in row 5, columns 2 and 3 of the 2nd STS-1 of the STS-48 |

Furthermore, Table 9 indicates how node 101-i knows which STS-1's in the STS-N are to be associated with which automatic protection switching channels. In some alternative embodiments of the present invention Tables 7, 8 and 9 are consolidated into a single table.

TABLE 9
Association of STS-1's in STS-48 with Automatic Protection
Switching Channels

| STS-1 | Associated APS Channel |
|---|---|
| 1 | m = 1 (traffic) |
| . . . | . . . |
| 6 | m = 1 (traffic) |
| 7 | m = 1 (protection) |
| . . . | . . . |
| 12 | m = 1 (protection) |
| 13 | m = 2 (traffic) |
| . . . | . . . |
| 18 | m = 2 (traffic) |
| 19 | m = 2 (protection) |
| . . . | . . . |
| 24 | m = 2 (protection) |
| 25 | empty or carrying other traffic |
| 48 | empty or carrying other traffic |

In accordance with the illustrative embodiment, node 101-i is populated with the data in Tables 7, 8, and 9 at the time of establishing the ring and at the time of provisioning or reprovisioning each

When node 101-i receives two or more STS-N's that are each associated with rings, ADM/CC 403 enables node 101-i to multiplex the STS-1's and transmit them via a single optical fiber while maintaining their association with their respective rings.

To fuse the three ring networks into a mesh network, intelligent interconnectivity between the rings is provided at “ring interworking nodes.” A ring interworking node in a node in mesh network 100 that provides a logical conduit between two or more ring networks and provides for the recovery of mesh network 100 in the event of the failure of another ring interworking node. Nodes 101-2, 101-3, 101-4, and 101-7 in mesh network 100 are ring interworking nodes. A ring interworking node:

i. can transfer traffic (e.g., one or more STS-1's, etc.) between one ring and another ring during nominal operation, and

ii. can monitor, originate, access, modify or terminate line overhead (e.g., payload pointer bytes, automatic protection switching bytes, error monitoring bytes, etc.) in a SONET/SDH frame, and

iii. can initiate or terminate the transfer of traffic between one ring and a second ring based on the failure of a network element in either ring, and

iv. can alter the operation (e.g., the routing of traffic, etc.) of one ring based on the failure of a network element in other ring.

The presence of ring interworking nodes in mesh network 100 enables a protected service to be provisioned across mesh network 100 and the failure of any network element to handled in well-known fashion using the automatic protection switching channels for the affected rings.

In accordance with the illustrative embodiment, each of rings #1, #2, and #3 operate as a Bidirectional Line Switched Ring (“BLSR”). In some alternative embodiments of the present invention, however, some or all of the rings operate as a Unidirectional Path Switched Ring (“UPSR”).

For example, the presence of ring interworking nodes in mesh network 100 enables a protected service to be provisioned from node 101-1 to node 101-7. A protected service from node 101-1 to node 101-7 can be provisioned through many paths. For example, one such path goes on ring #1 from ring #1-node #0 (in node 101-1) to ring #l-node #3 (in node 101-4) to ring #1-node #2 (in node 101-3) out of ring #1 and into ring #3 at ring #3-node #0 (also in node 101-3) to ring #3-node #2 (in node 101-7). In this case, node 101-3, which is a ring interworking node, is the “primary transfer node” for the service between ring #1 and ring #3. It will be clear to those skilled in the art how to determine the other paths that could be provisioned between node 101-1 and node 101-7.

At the time of provisioning the service, each of the interworking nodes in ring #1 and ring #3 (i.e., node 101-2 and node 101-4) need to be programmed what to do in both ring #1 and ring #3 in the event of the failure of the primary transfer node. In this case, node 101-4 is designated the “secondary transfer node,” which means that in the event of the failure of the primary transfer node it becomes responsible for transferring the traffic between ring #1 and ring #3. It will also be clear to those skilled in the art that node 101-2 could alternatively been designated the secondary transfer node, but in that case, the service would have been routed from ring #1 and to ring #2 for delivery to node 101-7. In any case, it will be clear to those skilled in the art how to provision a service and its protection bandwidth through any mesh network comprising a plurality of interlocking ring networks.

In this example, between ring #1-node #0 (in node 101-1) and ring #1-node #2 (in node 101-3), the service is protected, in well-known fashion, by the automatic protection switching channel and the protection bandwidth in ring #1. For example, a failure of the transmission facilities between ring #1-node #3 (in node 101-4) and ring #1-node #2 (in node 101-3) would be detected by ring #1-node #3 (in node 101-4) and ring #1-node #2 (in node 101-3) in well-known fashion, and the nature and location of the failure promulgated to the nodes in ring #1 via the automatic protection switching channel for ring #1. Furthermore, ring #1-node #3 (in node 101-4) would switch back the traffic headed for ring #1-node #2 (in node 101-3) in the protection bandwidth to ring #1-node #0 (in node 101-1) and ring #l-node #1 (in node 101-2) for delivery to ring #l-node #2 (in node 101-3). In this way, all facilities failures in ring #1 are handled in well-known fashion.

Between ring #3-node #0 (in node 101-3) and ring #3-node #2 (in node 101-7), the service is protected, in well-known fashion, by the automatic protection switching channel and the protection bandwidth in ring #3. For example, a failure of the transmission facilities between ring #3-node #0 (in node 101-3) and ring #3-node #2 (in node 101-7) would be detected by ring #3-node #0 (in node 101-3) and ring #3-node #2 (in node 101-7) in well-known fashion, and the nature and location of the failure promulgated to the nodes in ring #3 via the automatic protection switching channel for ring #3. Furthermore, ring #3-node #0 (in node 101-3) would switch back the traffic headed for ring #3-node #2 (in node 101-7) in the protection bandwidth to ring #3-node #4 (in node 101-10), ring #3-node #4 (in node 101-9), and ring #3-node #3 (in node 101-8) for delivery to ring #3-node #2 (in node 101-7). In this way, all facilities failures in ring #3 are handled in well-known fashion.

A failure in ring interworking node 101-3 itself is protected by ring interworking node 101-4. For example, the failure of ring interworking node 101-3—the primary transfer node for that service between ring #1 and ring #3—would be detected by ring interworking node 101-4—the secondary transfer node for that service between ring #1 and ring #3—by monitoring the automatic protection switching channels for both ring #1 and ring #3. Upon learning of the failure of the primary transfer node, the secondary transfer node initiates the transfer of the traffic associated with the service out of ring #1 at ring #3 (in node 101-4) and into ring #3 at ring #3-node #1 in protection bandwidth for ring #3 and in a direction that bypasses the primary transfer node to ring #3-node #2 (in node 101-7).

Each service through mesh network 100 and its protection bandwidth are advantageously provisioned in this way and each ring interworking node programmed how to respond to each possible failure on a service-by-service basis. In this way, the failure of any network element is handled quickly and efficiently and in a distributed manner.

It is to be understood that the above-described embodiments are merely illustrative of the present invention and that many variations of the above-described embodiments can be devised by those skilled in the art without departing from the scope of the invention. It is therefore intended that such variations be included within the scope of the following claims and their equivalents.

What is claimed is:

1. A telecommunications network comprising:
a first SONET/SDH ring;
a second SONET/SDH ring; and
a node that monitors the status of an automatic protection switching channel in said first SONET/SDH ring and that alters the operation of said second SONET/SDH ring based on the status of an automatic protection switching channel in said first SONET/SDH ring.

2. The telecommunications network of claim 1 wherein said controller also monitors the status of an automatic protection switching channel in said second SONET/SDH ring and that affects the routing of traffic in said first SONET/SDH ring based on the status of an automatic protection switching channel in said second SONET/SDH ring.

3. The telecommunications network of claim 1 further comprising a switch that switches traffic between said first SONET/SDH ring and said second SONET/SDH ring based on the status of an automatic protection switching channel in said first SONET/SDH ring.

4. The telecommunications network of claim 1 further comprising a switch that switches traffic between said first SONET/SDH ring and said second SONET/SDH ring based on the status of an automatic protection switching channel in said second SONET/SDH ring.

5. A telecommunications network comprising:
a mesh network that comprises a first plurality of nodes, wherein said mesh network defines a first address space and wherein each of said first plurality of nodes has a unique address in said first address space; and
a first ring that comprises a second plurality of nodes, wherein said first ring defines a second address space and wherein each of said second plurality of nodes has a unique address in said second address space;
wherein said second plurality of nodes is a proper non-empty subset of said first plurality of nodes.

6. The telecommunications network of claim 5 further comprising:
a second ring that comprises a third plurality of nodes, wherein said second ring defines a third address space and wherein each of said third plurality of nodes has a unique address in said third address space;
wherein said third plurality of nodes is a proper non-empty subset of said first plurality of nodes.

7. The telecommunications network of claim 6 wherein at least one node exists that is common to both said second plurality of nodes and said third plurality of nodes.

8. The telecommunications network of claim 6 further comprising an optical fiber that carries a first frame that comprises:
(1) a first subframe that is associated with said first ring; and
(2) a second subframe that is associated with said second ring.

9. The telecommunications network of claim 6 further comprising an optical fiber that carries a first frame that comprises:
(1) a first automatic protection switching channel that is associated with said first ring; and
(2) a second automatic protection switching channel that is associated with said second ring.

10. The telecommunications network of claim 6 further comprising an optical fiber that carries a first frame that comprises:
(1) a first subframe that comprises SONET/SDH K₁ and K₂ line overhead bytes that are associated with said first ring; and
(2) a second subframe that comprises SONET/SDH K₁ and K₂ line overhead bytes that are associated with said second ring.

11. A telecommunications network comprising:
a first ring that comprises a first plurality of nodes, wherein said first ring defines a first address space and wherein each of said first plurality of nodes is identified by a unique address in said first address space; and
a second ring that comprises a second plurality of nodes, wherein second ring defines a second address space and wherein each of said second plurality of nodes is identified by a unique address in said second address space;
wherein there is at least one node that has an address in the address space of said first ring and an address in the address space of said second ring; and
wherein each node in said first plurality of nodes and said second plurality of nodes is also identified by a unique address in the address space of a mesh network.

12. The telecommunications network of claim 11 further comprising an optical fiber that carries a first frame that comprises:
(1) a first subframe that is associated with said first ring; and
(2) a second subframe that is associated with said second ring.

13. The telecommunications network of claim 11 further comprising an optical fiber that carries a first frame that comprises:
(1) a first automatic protection switching channel that is associated with said first ring; and
(2) a second automatic protection switching channel that is associated with said second ring.

14. The telecommunications network of claim 11 further comprising an optical fiber that carries a first frame that comprises:
(1) a first subframe that comprises SONET/SDH K₁ and K₂ line overhead bytes that are associated with said first ring; and
(2) a second subframe that comprises SONET/SDH K₁ and K₂ line overhead bytes that are associated with said second ring.
